(19) United States
(12) Patent Application Publication
(10) Pub. No.: US 2025/0189590 A1
(43) Pub. Date: Jun. 12, 2025

(54) Method for Determining a Thermal Runaway of an Electric Energy Storage Unit of an at Least Partially Electrically Operated Motor Vehicle, Computer Program Product, and Electronic Computing Device

(71) Applicant: Mercedes-Benz Group AG, Stuttgart (DE)

(72) Inventors: Jan Philipp SCHMIDT, Creussen (DE); Philipp KOMHARD, Boeblingen (DE)

(21) Appl. No.: 18/721,065

(22) PCT Filed: Aug. 8, 2023
(86) PCT No.: PCT/EP2023/071955

§ 371 Date: Jun. 17, 2024

(30) Foreign Application Priority Data
Aug. 29, 2022 (DE) 10 2022 003 147.7

(51) Int. Cl. G01R 31/3842; G01R 31/371; G01R 31/378; G01R 31/52; H01M 10/48

(52) U.S. Cl. CPC G01R 31/3842; G01R 31/371; G01R 31/378; G01R 31/52; H01M 10/488; H01M 2220/20

(57) ABSTRACT

A method for determining a thermal runaway of an electric energy storage unit of an operated motor vehicle includes continuous monitoring of the electric energy storage unit by at least one diagnostic method of an electric energy storage unit based on a diagnostic signal, determining a frequency of the anomaly when the anomaly is detected in the diagnostic signal, determining dynamics of the anomaly when the anomaly is detected in the diagnostic signal, continuous monitoring of a communication line by a limited anomaly counter, comparing the limited anomaly counter with an unlimited anomaly counter when the anomaly is detected inside the communication line and generating a differential signal on the basis thereof, and determining the thermal runaway on the basis of the determined frequency and the determined dynamics and the differential signal.

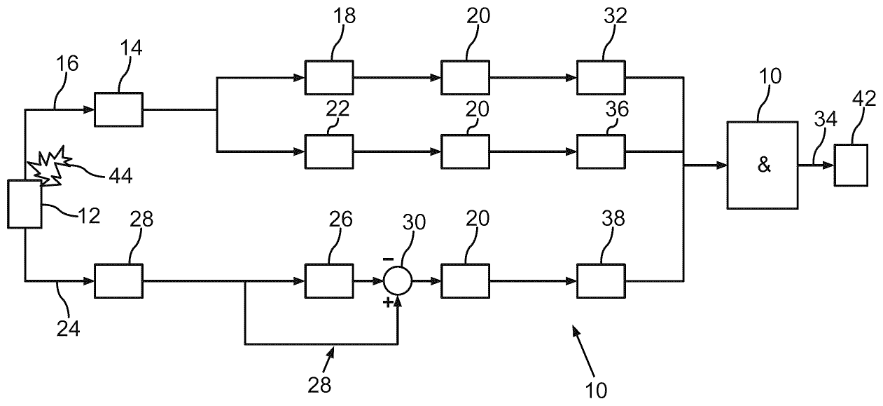

### BACKGROUND AND SUMMARY OF THE INVENTION

The invention relates to a method for determining a thermal runaway of an electric energy storage unit of an at least partially electrically operated motor vehicle by means of an electronic computing device of the motor vehicle. The invention further relates to a computer program product and to an electronic computing device.

It is already known that if, for example, a thermal runaway can occur in a so-called traction battery as an electric energy storage unit of a motor vehicle, the occupants of the vehicle must be warned five minutes before a fire breaks out, for example. A combination of voltage measurement and insulation measurement is currently used in the vehicle for this purpose. If an undervoltage as well as an insulation fault are detected, an alarm is triggered. However, the measurement of the insulation fault is relatively prone to errors. Furthermore, the integration of a dedicated additional sensor, for example a pressure sensor, is also known. However, this leads to higher costs. Furthermore, the cell temperature itself can be considered. However, as not every battery cell is equipped with a sensor and depending on the installation location, may also not be well shielded from the hot gases, temperature sensors can also have a very large time lag. Merely measuring the cell voltage is unreliable because it can lead to frequent false warnings in this case. If, for example, a measuring line breaks, without a further signal to check plausibility, this would lead to a false warning due to an apparent undervoltage.

EP 3 843 195 A1 refers to a device for detecting the thermal runaway, to a battery system and to a method for detecting the thermal runaway of the battery system, wherein the device for detecting the thermal runaway comprises the following: a first measurement module for measuring temperature values of the multiple cells via at least one temperature sensor; a second measurement module for measuring an output voltage value of the battery system; and a controller for determining the validity of the detection of a thermal runaway based on the temperature value by monitoring data which is received from the first measurement module, and for detecting a thermal runaway of the battery system by selectively monitoring the temperature value or the output voltage value according to a result of the validity determination of the detection of a thermal runaway based on the temperature value.

The object of the present invention is to create a method, a computer program product and an electronic computing device, by means of which improved thermal runaway of an electric energy storage unit can be detected.

One aspect of the invention relates to a method for determining a thermal runaway of an electric energy storage unit of an at least partially electrically operated motor vehicle by means of an electronic computing device of the motor vehicle. The electric energy storage unit is continuously monitored by means of at least one diagnostic method for determining a current state of the electric energy storage unit based on a diagnostic signal. When an anomaly is detected in the diagnostic signal, a frequency of the anomaly in the diagnostic signal is determined over a predefined time period. Furthermore, when an anomaly is detected in the diagnostic signal, dynamics of the anomaly in the diagnostic signal are determined over a predefined time period. A communication line of the electric energy storage unit is monitored continuously by means of a limited anomaly counter. When an anomaly is detected inside the communication line, the limited anomaly counter is compared with an unlimited anomaly counter and a differential signal is generated on the basis thereof. The thermal runaway is determined on the basis of the determined frequency and the determined dynamics and the differential signal.

Therefore, it is possible that detection of thermal runaway inside of an electric energy storage unit can be improved.

Thus, in particular a thermal runaway of a battery cell or electric energy storage unit, in particular in the form of a lithium-ion battery, can be robustly detected without additional sensors. Since the cell electronic monitoring system is in any case a component of an electric energy storage unit, in particular a traction battery of a motor vehicle, a corresponding diagnosis is implemented to achieve so-called ASIL safety, and thus there are no component costs, and the expansion of the software is also low. This means that thermal runaway can already be detected with existing systems or processes with reduced effort.

In particular, this involves the use of the cell voltage measurement, the performance of diagnostics for the cell voltage measurement, the calculation of signals derived from the diagnostics and the threshold connection, and the combination of the diagnostics using corresponding AND operations, in order to be able to determine the thermal runaway.

In particular it is therefore provided that the cell electronic monitoring system has the task of measuring the cell voltages and cell temperatures. Since these values are used in order to meet safety targets with an ASIL rating, they are checked in any case for correct function by means of diagnostics. These diagnostics are triggered if such an error/anomaly is present. With thermal runaway, many of these errors occur, and also sometimes simultaneously. The challenge is to separate the thermal runaway from an actual error. To make matters worse, some hardware faults, in particular when a thermal runaway does not occur, also trigger several diagnostics. In order to better distinguish between the two cases, the dynamics of the errors or anomalies and the number of simultaneously occurring errors or anomalies are taken into account.

Furthermore, frequent communication errors also occur during thermal runaway when transmitting via a so-called daisy chain, which corresponds to this communication line and can be designed as a CAN bus, for example. In the implementation with a so-called ASIC of analogue functional components, these errors are counted with a so-called PEC (Packet Error Counter). This PEC corresponds to the unlimited anomaly counter. However, as several packets can also be falsified under normal circumstances, for example when switching contactors, an investigation is also carried out here. For this purpose, the dynamics of the PEC are limited with a so-called rate limiter, i.e., the limited anomaly counter, and the difference to the actual PEC, which corresponds to the unlimited anomaly counter, is then determined. If this differential signal exceeds a threshold, this indicates thermal runaway.

Thus, the combination of the dynamics of the anomaly, the number of simultaneously occurring anomalies and the differential signal are used to draw conclusions about the thermal runaway, without obtaining false detections in particular.

According to a very advantageous embodiment, an interruption of a cell voltage line is monitored by means of the diagnostic method. In particular, this diagnostic method may be a diagnostic method already installed in the motor vehicle for monitoring the cell voltage measuring line. With this diagnostic method it can be checked whether an anomaly is present and its dynamics and frequency are monitored. This method may in particular be a so-called open wire method.

It has further proved to be advantageous if a switching state of a balancing semiconductor element is monitored by means of the diagnostic method. The balancing semiconductor element may in particular be a so-called balancing FET element. In particular it can therefore be checked whether this semiconductor element is switched off or is continuously switched on, for example. This diagnostic method may similarly be a diagnostic method already installed in the motor vehicle for monitoring the electric energy storage unit.

A further advantageous embodiment provides that a short circuit between adjacent pins on a circuit board of the electronic computing device is monitored by means of the diagnostic method. This is also a method already installed in the vehicle for monitoring the electric energy storage unit or the electronic computing device. In particular, this involves checking whether a short circuit between neighbouring GPIOs (general purpose input/output), i.e., the pins on the ASIC to which the temperature sensor is connected, for example, are being monitored.

Furthermore, the diagnostic method can be used to monitor a deviation of a second reference voltage source. This is also a method already installed in the motor vehicle for monitoring the electrical components, in particular the battery cells, whereby the thermal runaway can be determined in a simple manner.

It has further proved to be advantageous if a total voltage across a circuit board of the electronic computing device is monitored by means of the diagnostic method. In particular, the total voltage across the ASIC is thus monitored, in particular to determine whether this is unequal to the accumulated individual voltages. This method is similarly already installed in the motor vehicle or in the electric energy storage unit, so that thermal runaway can be inferred reliably and in a simple manner.

A further advantageous embodiment provides that the differential signal is generated only when a predefined threshold between the limited anomaly counter and the unlimited anomaly counter is exceeded. For example, rate limiting can be carried out for the limited anomaly counter at four faults per second. Should the threshold be above 20, for example, this can be taken as an indication that a fault/anomaly is present.

According to an advantageous embodiment, when a potential thermal runaway is determined, a warning message for an occupant in the motor vehicle is output on an output device of the motor vehicle. In particular, this warning message is output at least five minutes before the thermal runaway. The output device may be a haptic output device, an optical output device or an acoustic output device. In particular, different warning messages, for example an acoustic warning signal, an optical warning signal and a haptic warning signal can be output simultaneously.

The presented method is a computer-implemented method. Therefore, a further aspect of the invention relates to a computer program product comprising program code means which causes an electronic computing device to carry out a method according to the preceding aspect when the program code means are processed by the electronic computing device. In particular, the method is carried out by means of the electronic computing device. The computer program product can also be referred to as a computer program.

A further aspect of the invention therefore also relates to a computer-readable storage medium with computer program product.

Furthermore, the invention also relates to an electronic computing device for determining thermal runaway of an electric energy storage unit of an at least partially electrically operated motor vehicle, wherein the electronic computing device is designed to carry out a method according to the preceding aspect. In particular, the method is carried out by means of the electronic computing device.

For example, the electronic computing device has processors, circuits, in particular integrated circuits, and further electronic components, in order to be able to carry out corresponding method steps.

Similarly, the invention also relates to an at least partially electrically operated or fully electrically operated motor vehicle.

Advantageous embodiments of the method are considered advantageous embodiments of the computer program product, the electronic computing device and the motor vehicle. In particular, the electronic computing device and the motor vehicle have features in order to be able to carry out corresponding method steps.

Further advantages, features and details of the invention can be seen from the following description of a preferred exemplary embodiment and from the drawing. The features and combinations of features mentioned above in the description as well as the features and combinations of features mentioned below in the description of the figures and/or shown alone in the single figure can be used not only in the combination indicated in each case, but also in other combinations or on their own, without leaving the scope of the invention.

### BRIEF DESCRIPTION OF THE DRAWING

The only Figure shows a schematic block diagram according to one embodiment of the method.

### DETAILED DESCRIPTION OF THE DRAWING

In the Figure, identical or functionally identical elements are provided with the same reference signs.

The Figure shows a schematic block diagram according to one embodiment of an electronic computing device 10 for determining a thermal runaway of an electric energy storage unit 12 of an at least partially electrically operated motor vehicle. In the present exemplary embodiment, in particular a flow chart is shown. In particular, the electric energy storage unit 12 is continuously monitored by means of at least one diagnostic method 14 for determining a current state of the electric energy storage unit 12 based on a diagnostic signal 16. When an anomaly 44 is detected in the diagnostic signal 16, a frequency 18 of the anomaly 44 in the diagnostic signal 16 is determined over a predefined time period 20. Furthermore, when the anomaly 44 is detected in the diagnostic signal 16, the dynamics 22 of the anomaly 44 in the diagnostic signal 16 are determined over a predefined time period 20. Furthermore, continuous monitoring of a communication line 24 of the electric energy storage unit 12 takes place by means of a limited anomaly counter 26. When the anomaly 44 is detected inside the communication line 24, the limited anomaly counter 26 is compared with an unlimited anomaly counter 28 and a differential signal 30 is generated on the basis thereof. The thermal runaway is then in turn determined on the basis of the determined frequency 18, the determined dynamics 22 and the differential signal 30.

For this purpose, it can be provided in particular that a threshold comparison is carried out. For example, a first threshold 32 of greater than 100 can be provided for the measurement of the frequency 18. In other words, only when 100 or more anomalies 44 are detected can this lead to a warning signal 34 for thermal runaway. Furthermore, a second threshold 36 can be provided, which in turn describes the dynamics. For example, the dynamics may concern an amount of the derivative of the number of bits set and may, for example, comprise a second threshold 36 of ≥10. A third threshold 38 can be provided, which in turn describes the measurement of the communication faults occurring noticeably frequently, wherein this can be considered as >20, for example. Only when the threshold comparisons for all three have been classified as positive, i.e., the thresholds 32, 36 have been exceeded, are they combined into an AND operation 40. If all three thresholds 32, 36, 38 are exceeded, a warning message 34 is generated. The warning message 34 may be output on an output device 42 of the motor vehicle, for example. For example, the output device 42 may be designed as a display device, loudspeaker device or haptic device.

The time period 20 may be 20 seconds for example, or also another time span, e.g., 40 seconds.

As explained above, it is shown here that an AND operation 40 is provided. An alternative implementation, for example, is that instead of forming a threshold before the AND operation 40, an addition with weighting is carried out and only then is the threshold formed.

In particular, the Figure thus shows that the cell electronic monitoring system has the task of measuring the cell voltage and cell temperature. Since these values are used in order to meet safety targets with a corresponding ASIL rating, this is checked for correct function by means of the diagnostic method 14. Such diagnostics comprise the interruption of the cell voltage measuring line, for example, so-called open wire diagnostics. Furthermore, diagnostic methods 14 can also be used which monitor a balancing semiconductor element, for example. For example, it can be checked whether this semiconductor element is switched off or is continuously switched on. This can also be referred to as a balancing FET piece. Furthermore, the short circuit between adjacent circuit boards, so-called general-purpose input/output, can be checked. In particular, it is checked whether the corresponding pins on the ASIC, to which the temperature sensor is connected, for example, have a short circuit. Furthermore, a deviation of a second reference voltage source can also be used for monitoring. Furthermore, the total voltage across the ASIC can also be checked, for example to determine whether it is unequal to the summed individual voltages.

These diagnostic methods 14 are triggered if such an error/anomaly 44 is present. During thermal runaway, many of these faults occur and also sometimes simultaneously. The challenge is to separate the thermal runaway from an actual error. To make matters worse, some hardware faults that do not correspond to thermal runaway, also trigger several diagnostic methods 14. In to better distinguish between the two cases, the dynamics 22 as well as the frequency 18 of the anomaly 44 are taken into account.

Furthermore, frequent communication errors also occur during transmission via the communication line 24, in particular the so-called daisy chain, during thermal runaway. In the implementation with the ASIC of analogue devices, these errors are counted with a so-called unlimited anomaly counter 28 (Packet Error Counter-PEC). However, as several packets can also be falsified under normal circumstances, for example when switching contactors, a distinction is also carried out here. For this purpose, the dynamics of the PEC are limited by a limited anomaly counter 26, a so-called rate limiter, and the difference to the actual PEC is then determined. If this differential signal 30 exceeds a threshold, in particular presently the third threshold 38, this indicates thermal runaway.

The limited anomaly counter 26 can carry out rate limiting for example, at four faults or anomalies 44 per second.

Should the frequency 18, the dynamics 22 and the differential signal 30 exceed the corresponding thresholds 32, 36, 38, the thermal runaway is recognized on the basis of the AND operation 40 and the warning signal 34 is generated.

### LIST OF REFERENCE CHARACTERS

10 electronic computing device
12 electric energy storage unit
14 diagnostic method
16 diagnostic signal
18 frequency
20 time period
22 dynamics
24 communication line
26 limited anomaly counter
28 unlimited anomaly counter
30 differential signal
32 first threshold
34 warning message
36 second threshold
38 third threshold
40 AND operation
42 output device
44 anomaly

1.-10. (canceled)

11. A method for determining a thermal runaway of an electric energy storage unit (12) of an at least partially electrically operated motor vehicle via an electronic computing device (10) of the motor vehicle, comprising the steps of:
continuous monitoring of the electric energy storage unit (12) by a diagnostic method (14) for determining a current state of the electric energy storage unit (12) based on a diagnostic signal (16);
when an anomaly (44) is detected in the diagnostic signal (16), determining a frequency (18) of the anomaly (44) in the diagnostic signal (16) over a predefined time period (20);
when the anomaly (44) is detected in the diagnostic signal (16), determining dynamics (22) of the anomaly (44) in the diagnostic signal (16) over the predefined time period (20);
continuous monitoring of a communication line (24) of the electric energy storage unit (12) by a limited anomaly counter (26);
comparing the limited anomaly counter (26) with an unlimited anomaly counter (28) when the anomaly (44) is detected inside the communication line (24) and generating a differential signal (30) on a basis of the comparing; and
determining the thermal runaway on a basis of the determined frequency (18) and the determined dynamics (22) and the differential signal (30).

12. The method according to claim 11, wherein an interruption of a cell voltage measuring line is monitored by the diagnostic method (14).

13. The method according to claim 11, wherein a switching state of a balancing semiconductor element is monitored by the diagnostic method (14).

14. The method according to claim 11, wherein a short circuit between adjacent pins on a circuit board of the electronic computing device (10) is monitored by the diagnostic method (14).

15. The method according to claim 11, wherein a deviation of a reference voltage source is monitored by the diagnostic method (14).

16. The method according to claim 11, wherein a total voltage across a circuit board of the electronic computing device (10) is monitored by the diagnostic method (14).

17. The method according to claim 11, wherein the differential signal (30) is only generated when a predefined threshold between the limited anomaly counter (26) and the unlimited anomaly counter (38) is exceeded.

18. The method according to claim 11, wherein when a potential thermal runaway is determined, a warning message (34) for an occupant in the motor vehicle is output on an output device (42) of the motor vehicle.

19. A computer program product comprising program code which causes an electronic computing device (10) to carry out the method according to claim 11 when the program code is processed by the electronic computing device (10).

20. An electronic computing device (10) for determining a thermal runaway of an electric energy storage unit (12) of an at least partially electrically operated motor vehicle, wherein the electronic computing device (10) is configured to perform the method according to claim 11.
